(19) United States
(12) Patent Application Publication
(10) Pub. No.: US 2008/0138745 A1
(43) Pub. Date: Jun. 12, 2008

(54) POLYMER FOR HARD MASK OF SEMICONDUCTOR DEVICE AND COMPOSITION CONTAINING THE SAME

(75) Inventor: Jae Chang Jung, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-Si (KR)

(21) Appl. No.: 12/027,958

(22) Filed: Feb. 7, 2008

Related U.S. Application Data
(62) Division of application No. 11/417,605, filed on May 3, 2006.

(30) Foreign Application Priority Data
Dec. 15, 2005 (KR) 10-2005-0123859

(51) Int. Cl. G03F 7/26

(52) U.S. Cl. 430/319

(57) ABSTRACT

A polymer for hard mask and a composition containing the same, which may be useful in the manufacture of next generation semiconductor devices. When an underlying layer pattern of a semiconductor device, using a polyamic acid having a strong heat resistance, a polyamic acid film is formed by a spin-coating method and an additional thermal process and used as a hard mask, thereby facilitating etching of fine patterns.

### CROSS-REFERENCE TO RELATED APPLICATIONS

This is a division of U.S. application Ser. No. 11/417,605 filed May 3, 2006, which in turn claims the priority benefit of Korean application 10-2005-0123859 filed Dec. 15, 2005, the entire respective disclosures of which are incorporated herein by reference.

### BACKGROUND OF THE DISCLOSURE

1. Field of the Disclosure

The disclosure relates to a polymer for hard mask of a semiconductor device and a composition containing the same. More specifically, the disclosure relates to an organic polymer for forming a hard mask, which are useful in processes for etching fine patterns, and a composition containing the organic polymer.

2. Description of the Related Technology

In order to prevent collapse of fine patterns of less than 70 nm, a photoresist film is required to have a thickness of less than 100 nm. However, because the thickness of less than 100 nm is not enough to endure an etching process of a lower layer, a new hard mask is required such as an amorphous carbon film.

The amorphous carbon that has the properties of organic materials can be thickly coated and shows a sufficient selectivity when the lower layer is etched. As a result, the amorphous carbon can be used as a hard mask for etching the thick lower layer even when the photoresist film is thinly formed. This is also caused by that a silicon oxide nitride film that serves as a different hard mask can be deposited over the hard mask consisting of the amorphous carbon because the amorphous carbon can endure at high temperature of over 400° C.

FIGS. 1a through 1e are cross-sectional diagrams illustrating a conventional method for forming an underlying layer pattern of a semiconductor device using the above-described amorphous carbon film as a hard mask.

Referring to FIG. 1a, an underlying layer 12, an amorphous carbon film 14, a silicon oxide nitride film 16, an anti-reflective coating (hereinafter abbreviated to “ARC”) film 18 and a photoresist film 20 are sequentially formed on a semiconductor substrate 10. The amorphous carbon film 14 is formed at a thickness ranging from 100 nm to 800 nm by a chemical vapor deposition equipment. The photoresist film 20 is formed at a thickness ranging from 40 nm to 200 nm.

Referring to FIG. 1b, the photoresist film 20 is selectively exposed and developed to form a pattern of the photoresist film 20.

Referring to FIG. 1c, a common etching process is performed to remove sequentially the lower ARC film 18 and the silicon oxide nitride film 16 with the pattern of the photoresist film 20 as an etching mask, thereby forming a pattern of the ARC film 18 and a pattern of the silicon oxide nitride film 16.

Referring to FIG. 1d, a common etching process is performed to remove the lower amorphous carbon film 14 with the pattern of the photoresist film 20, the pattern of the ARC film 18 and the pattern of the silicon oxide nitride film 16 which remain after the above etching process, thereby forming a pattern of the amorphous carbon film 14.

Referring to FIG. 1e, the lower underlying layer 12 is etched with the pattern of the amorphous carbon film 14 and the residual patterns after the above process to form a pattern of the underlying layer 12. Then, the residual patterns used as etching masks are removed by cleaning.

As noted above, the additional chemical vapor deposition equipment and a chemical vapor deposition gas have been conventionally required to deposit the amorphous carbon film 14 when the pattern of the underlying layer 12 is formed.

### SUMMARY OF THE DISCLOSURE

Disclosed herein are an organic polymer having a strong heat resistance for forming a hard mask useful in processes for etching fine patterns of a semiconductor device (instead of an amorphous carbon), and a composition containing the organic polymer. Also disclosed herein is a method for manufacturing a semiconductor device comprising a step of forming an underlying layer pattern with a hard mask, the hard mask having been formed by the disclosed composition containing the organic polymer.

### BRIEF DESCRIPTION OF THE DRAWINGS

For a more complete understanding of the invention, reference should be made to the following detailed description and accompanying drawings wherein:

FIGS. 1a through 1e are cross-sectional diagrams illustrating a conventional method for forming an underlying layer pattern of a semiconductor device;

FIGS. 2a through 2e are cross-sectional diagrams illustrating a disclosed method for forming an underlying layer pattern of a semiconductor device;

FIG. 3 is a NMR spectrum of a polyamic acid obtained from Example 1;

FIG. 4 is a TGA graph of a polyamic acid obtained from Example 1; and

FIG. 5 is a cross-sectional SEM photograph illustrating an underlying layer pattern obtained from Example 3.

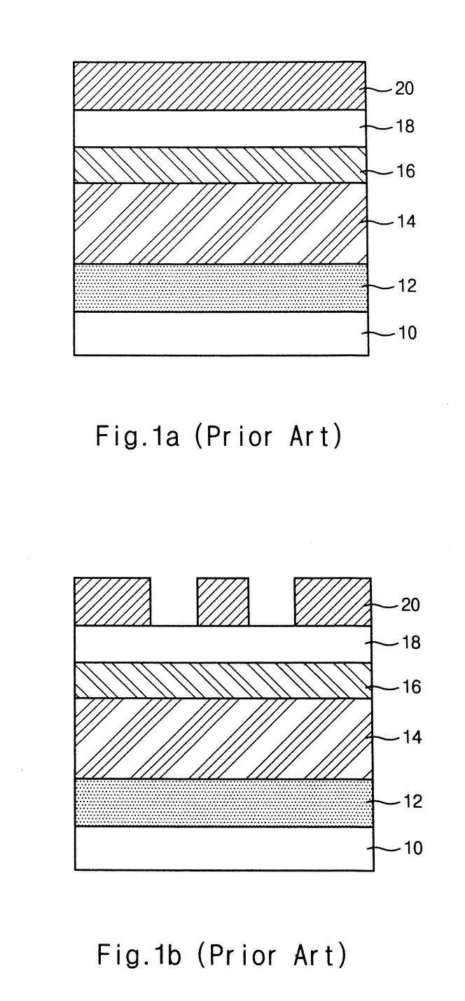

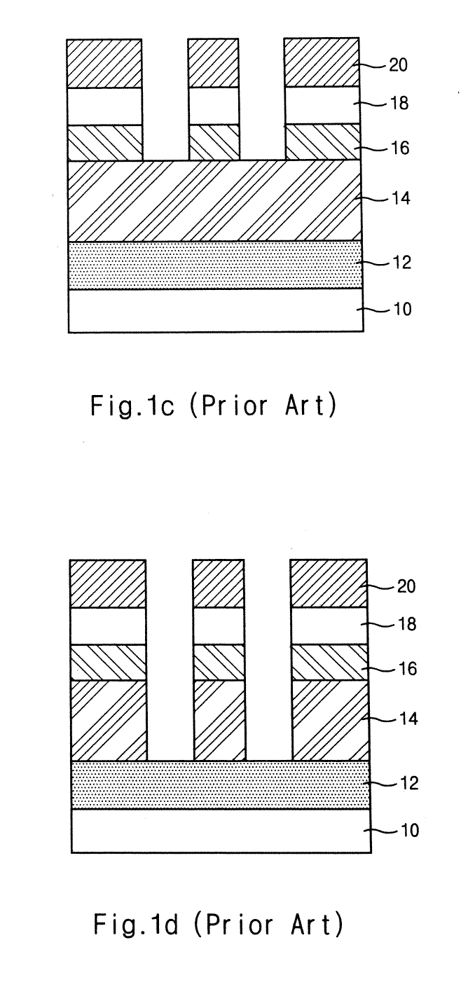

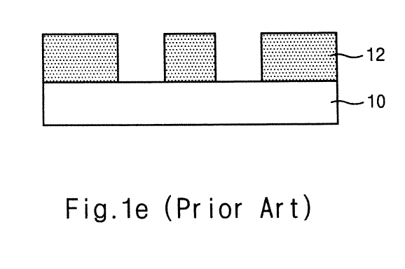

### DETAILED DESCRIPTION OF THE PRESENTLY PREFERRED EMBODIMENTS

Disclosed herein is a polyamic acid that can be used to form a hard mask useful in an etching process to form an underlying layer pattern of a semiconductor device. The polyamic acid is obtained by reacting a diamine compound and an anhydride in a solvent by a general method. The diamine compound includes 4,4′-diaminodiphenyl sulfone or phenylenediamine, the anhydride includes 1,2,4,5-benzenetetracarboxylic dianhydride or 3,3′,4,4′-benzophenonbenzenetetracarboxylic dianhydride, and the reaction solvent includes dimethylacetateamide, dimethylsulfoxide or dimethylformamide.

The polyamic acid is preferably represented by Formula 1 (shown below) and is obtained by reacting 1,2,4,5-benzenetetracarboxylic dianhydride of Formula 2 (shown below) and 4,4′-diaminodiphenyl sulfone of Formula 3 (shown below) in a dimethylacetateamide solvent.

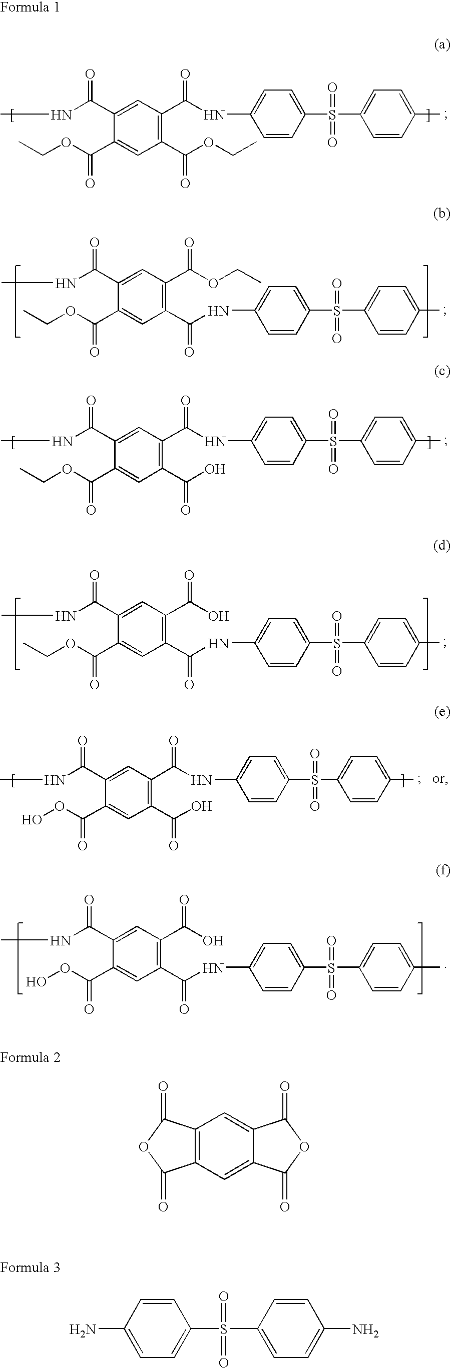

Also, disclosed herein is a composition for a hard mask. The composition for a hard mask includes a polyamic acid, a cross-linking agent and an organic solvent.

The cross-linking agent preferably is a melamine derivative, and the melamine derivative preferably is 2,4,6-tris(dimethoxymethylamino)-1,3,5-triazine of Formula 4 (shown below).

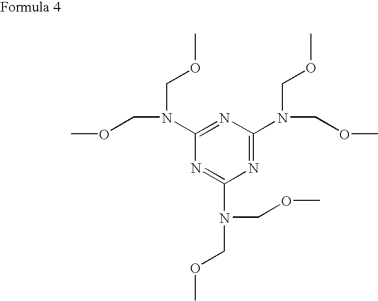

The cross-linking agent is present in an amount ranging from 1 to 10 parts by weight, based on 100 parts by weight of the polyamic acid. The cross-linking reaction slightly occurs when the cross-linking agent is present in the amount of less than 1 part by weight, and the etching resistance is reduced when the cross-linking agent is present in the amount of over 10 parts by weight.

The organic solvent is selected from the group consisting of cyclohexanone, cyclopentanone, γ-butyrolactone, and mixtures thereof. Preferably, the organic solvent is present in an amount ranging from 20 to 5000 parts by weight, based on 100 parts by weight of the polyamic acid. The coating property is degraded and the coating does not maintain uniform thickness when the organic solvent is present in the amount of less than 20 parts by weight. The organic solvent is too thinly coated to serve as a hard mask when the organic solvent is present in the amount of over 5000 parts by weight.

Also disclosed herein is a method for manufacturing a semiconductor device. The method includes (a) forming an underlying layer over a semiconductor substrate; (b) forming a stack structure pattern of first hard mask, a second hard mask and photoresist layer; and, (c) patterning the underlying layer using the stack structure pattern as an etching mask, wherein said first hard mask is formed of a polyamic acid film and said second hard mask is formed of an inorganic film. The second hard mask film includes a silicon oxide nitride film, a silicon oxide film, or a silicon nitride film. Before the photoresist film is formed on the second hard mask film, an ARC film is further formed on the hard mask film.

Also, disclosed herein is a method for using the above-described polyamic acid film as a hard mask in a photoresist pattern forming process. The polyamic acid film is formed by spin-coating the disclosed composition for a hard mask and drying it.

Hereinafter, the disclosed method for manufacturing a semiconductor device is explained with reference to the accompanying drawings.

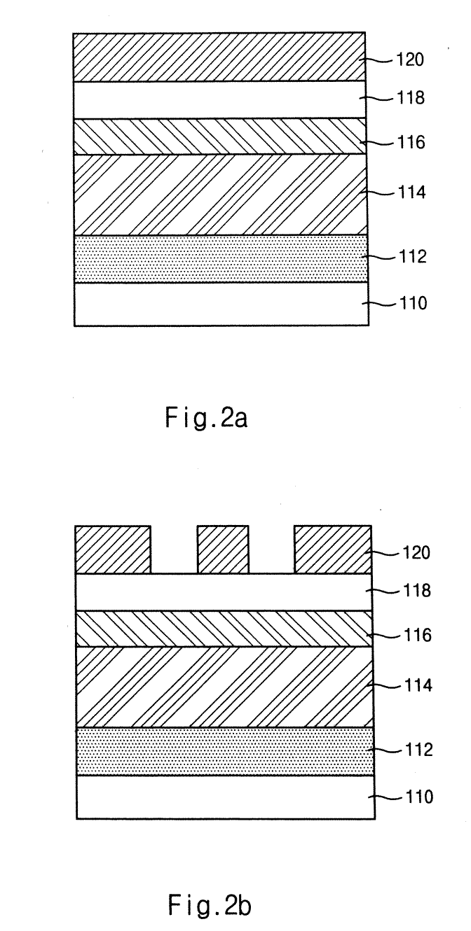

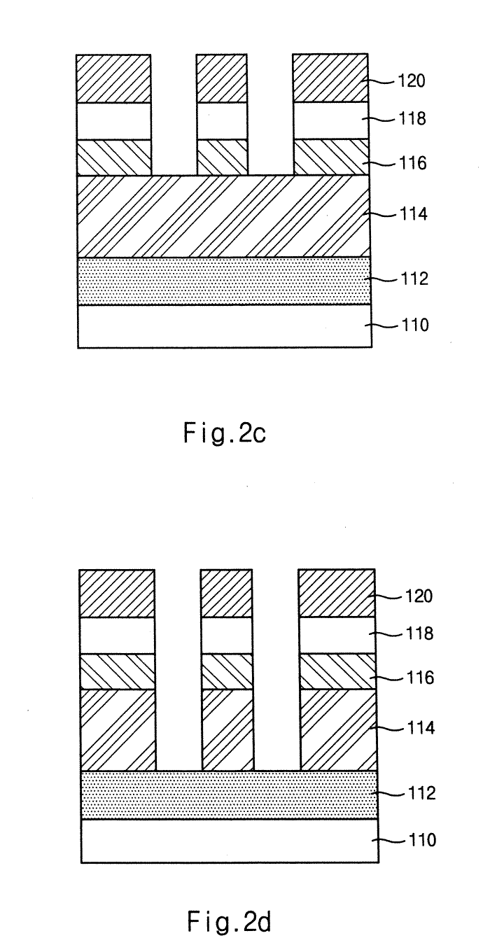

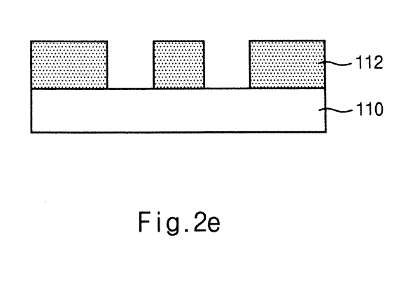

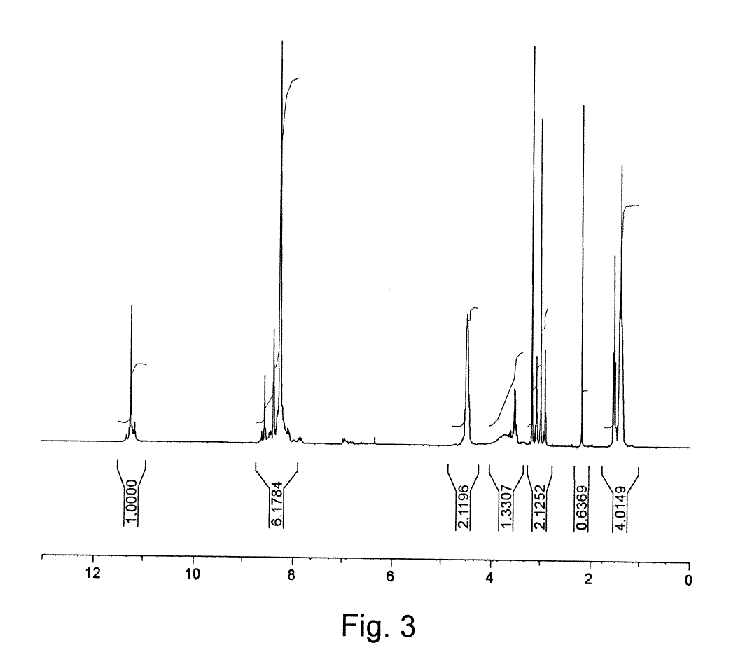

FIGS. 2a through 2e are cross-sectional diagrams illustrating a disclosed method for forming an underlying layer pattern of a semiconductor device, that is, a method for forming an underlying layer pattern with the above-described polyamic acid film as a hard mask.

Referring to FIG. 2a, an underlying layer 112, a polyamic acid film 114 as a first hard mask, a silicon oxide nitride film 116 as a second hard mask, an ARC film 118 and a photoresist film 120 are sequentially formed on a semiconductor substrate 110. The polyamic acid film 114 is formed at a thickness ranging from 30 nm to 1000 nm by spin-coating the disclosed composition for a hard mask. The photoresist film 120 is formed at a thickness ranging from 30 nm to 300 nm.

Referring to FIG. 2b, the photoresist film 120 is selectively exposed and developed to form a pattern of the photoresist film 120.

Referring to FIG. 2c, a dry etching process is performed to remove sequentially the lower ARC film 118 and the silicon oxide nitride film 116 with the pattern of the photoresist film 120 as an etching mask, thereby forming a pattern of the ARC film 118 and a pattern of the silicon oxide nitride film 116.

Referring to FIG. 2d, a dry etching process is performed to remove the lower polyamic acid film 114 with the pattern of the photoresist film 120, the pattern of the ARC film 118 and the pattern of the silicon oxide nitride film 116 which remain after the above etching process, thereby forming a pattern of the polyamic acid film 114.

The dry etching process is performed with a gas selected from the group consisting of O₂, NH₃, N₂, H₂, CH₄ and mixtures thereof. Generally, the combination of O₂ and N₂ or H₂ and N₂ is used. Although the power can be variously applied depending on etching equipment, used gas or process kinds as etching conditions, the source RF power ranges 300 W to 1000 W, and the bias power ranges from 0 W to 300 W.

Referring to FIG. 2e, the lower underlying layer 112 is etched with the pattern of the polyamic acid film 114 and the residual patterns after the above process to form a pattern of the underlying layer 112 at a thickness ranging from 30 nm to 200 nm. Then, the residual patterns used as etching masks are removed.

As mentioned above, the polyamic acid film 114 which is formed by a simple spin-coating method can be used as a hard mask when the pattern of the underlying layer 112 is formed. Also, the silicon oxide nitride film 116 can be deposited on the polyamic acid film 114 because the polyamic acid has a strong heat resistance like a conventional amorphous carbon.

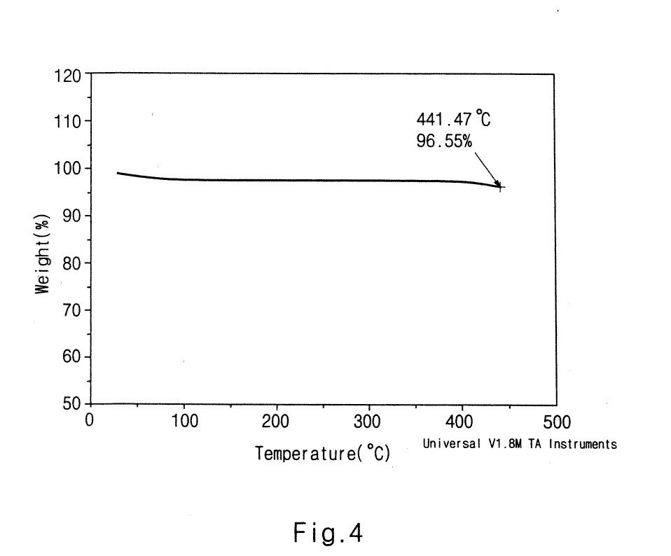

FIG. 4 is a TGA (Thermogravimetric Analysis) data graph as thermal analysis data that shows heat resistance of the polyamic acid film.

The disclosed compositions will be described in detail by referring to examples below, which are not intended to limit the present invention.

### Example 1

### Preparation of a Polyamic Acid

1,2,4,5-benzenetetracarboxylic dianhydride of Formula 2 (6.544 g) and 4,4′-diaminodiphenyl sulfone of Formula 3 (7.449 g) were dissolved in dimethylacetamide (107 g), and reacted for 24 hours. After reaction, triethylamine (15.1 g) was added therein and stirred for about 24 hours. Then, ethyl iodide (38.55 g) was added therein and reacted for 24 hours.

After reaction, the resulting mixture was precipitated in distilled water, washed with acetone and then dried to obtain the disclosed polyamic acid of Formula 1 which is a polymer for hard mask as light brown solid (yield: 85%). FIG. 3 is a NMR spectrum of the synthesized polyamic acid, and FIG. 4 is a graph illustrating TGA data of the polyamic acid.

### Example 2

### Preparation of a Composition for a Hard Mask

The polyamic acid (10 g) of Formula 1 obtained from Example 1, and 2,4,6-tris(dimethoxymethylamino)-1,3,5-triazine (0.6 g) of Formula 4 were dissolved in cyclohexnone (70 g) to obtain a disclosed composition for a hard mask.

### Example 3

### Formation of a Polyamic Acid Film and a Nitride Film Pattern

A SiO₂ film was formed at a thickness of 350 nm on a silicon wafer, and a nitride film was formed at a thickness of 100 nm thereon. Then, the composition for a hard mask obtained from Example 2 was spin-coated. After spin-coating, the resulting structure was baked at 200° C. for 2 minutes, and then baked at 400° C. for 2 minutes to form a polyamic acid film at a thickness of 400 nm. Next, a silicon oxide nitride film was formed at a thickness of 60 nm on the polyamic acid film, and an ARC film composition (DAR202BARC manufactured by Dongjin SemiChem Co., Ltd.) was coated over the silicon oxide nitride film to form an ARC film.

Thereafter, photoresist (AR1221J manufactured by Japan Synthetic Rubber Co., Ltd.) was coated on the ARC film, and soft-baked at 130° C. for 90 seconds to form a photoresist film at a thickness of 200 nm. The photoresist film was exposed with an ArF exposer, and post-baked at 130° C. for 90 seconds. After post-baking, the resulting structure was developed in 2.38 wt % TMAH aqueous solution for 40 seconds to obtain a 80 nm photoresist pattern.

Then, the lower ARC film and the silicon oxide nitride film were selectively etched with the photoresist pattern as an etching mask to form an ARC film pattern and a silicon oxide nitride film pattern. The lower polyamic acid film was selectively etched with the above patterns as etching masks to form a polyamic acid film pattern. The lower nitride film and the SiO₂ film were etched with the above pattern including the polyamic acid film as an etching mask to form a 80 nm pattern (etching condition: 10O₂+90N₂, source RF power: about 700 W, bias power: about 150 W).

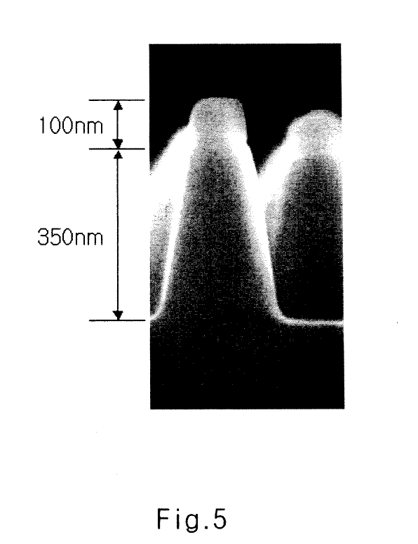

FIG. 5 is a cross-sectional SEM photograph of the SiO₂ film (thickness: 350 nm) and the nitride film (thickness: 100 nm) which remain after the above patterns including the polyamic acid pattern are removed.

As described above, when an underlying layer pattern of a semiconductor device is formed, using a polyamic acid having a strong heat resistance instead of a conventional amorphous carbon, a polyamic acid film is formed by a spin-coating method and used as a hard mask, thereby facilitating etching of fine patterns.

What is claimed is:

1. A method for manufacturing a semiconductor device comprising:
forming an underlying layer over a semiconductor substrate;
forming a stack structure pattern of a first hard mask, a second hard mask, and photoresist layer; and
patterning the underlying layer using the stack structure pattern as an etching mask,
wherein said first hard mask is formed of a hard mask composition comprising a polyamic acid represented by Formula 1: 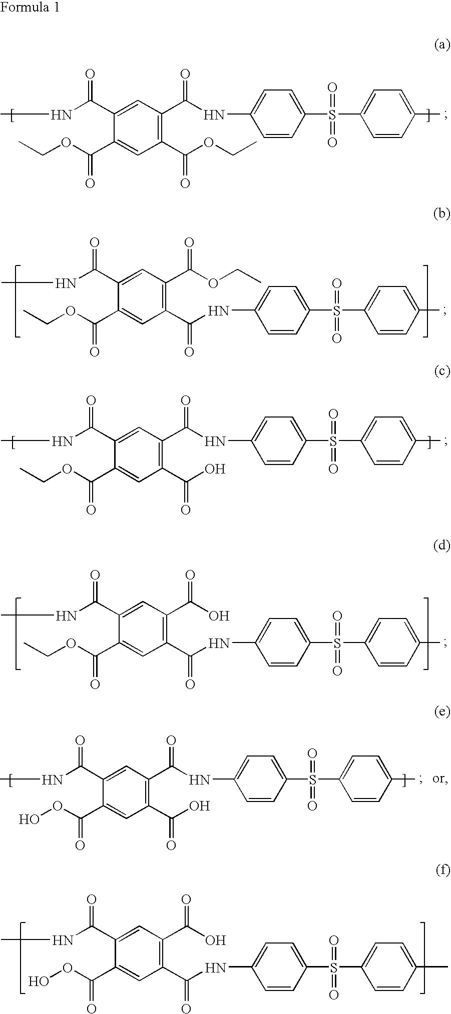
a cross-linking agent, and an organic solvent; and,
said second hard mask is formed of an inorganic film.

2. The method of claim 1, comprising forming the polyamic acid film in a thickness ranging from 30 nm to 1000 nm, and forming the photoresist film in a thickness ranging from 30 nm to 300 nm.

3. The method of claim 1, wherein the second hard mask film is a silicon oxide nitride film, a silicon oxide film, or a silicon nitride film.

4. The method of claim 1, wherein the cross-linking agent is a melamine derivative.

5. The method of claim 4, wherein the cross-linking agent is 2,4,6-tris(dimethoxymethylamino)-1,3,5-triazine represented by Formula 4:

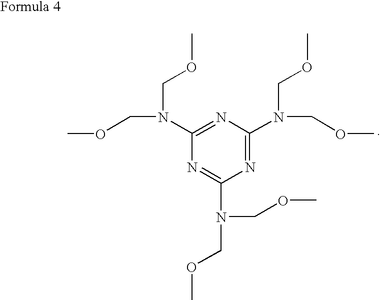

6. The method of claim 1, wherein the organic solvent is selected from the group consisting of cyclohexanone, cyclopentanone, γ-butyrolactone, and mixtures thereof.

7. The method of claim 1, wherein organic solvent is present in an amount ranging from 20 parts by weight to 5000 parts by weight, based on 100 parts by weight of the polyamic acid, and the cross-linking agent is present in an amount ranging from 1 part by weight to 10 parts by weight based on 100 parts by weight of the polyamic acid.

8. A method for manufacturing a semiconductor device, comprising:
forming an underlying layer over a semiconductor substrate;
forming a stack structure pattern of a first hard mask, a second hard mask, and a photoresist layer; and
patterning the underlying layer using the stack structure pattern as an etching mask, wherein said first hard mask is formed of a hard mask composition comprising a polyamic acid represented by Formula 1, a cross-linking agent represented by Formula 4: and an organic solvent; 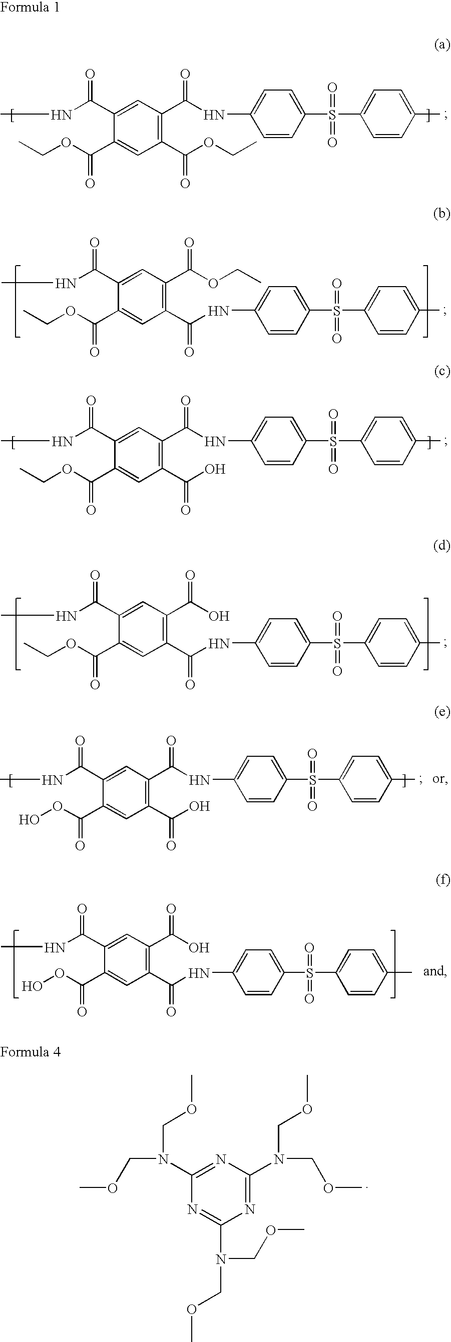
said second hard mask is formed of an inorganic film.

9. The method of claim 8, comprising forming the polyamic acid film in a thickness ranging from 30 nm to 1000 nm, and forming the photoresist film in a thickness ranging from 30 nm to 300 nm.

10. The method of claim 8, wherein the second hard mask film is a silicon oxide nitride film, a silicon oxide film, or a silicon nitride film.

11. The method of claim 8, wherein the organic solvent is selected from the group consisting of cyclohexanone, cyclopentanone, γ-butyrolactone, and mixtures thereof.

12. The hard mask composition of claim 8, wherein the organic solvent is present in an amount ranging from 20 parts by weight to 5000 parts by weight, based on 100 parts by weight of the polyamic acid, and the cross-linking agent is present in an amount ranging from 1 part by weight to 10 parts by weight based on 100 parts by weight of the polyamic acid.
